(19) United States
(12) Patent Application Publication
(10) Pub. No.: US 2012/0071086 A1
(43) Pub. Date: Mar. 22, 2012

(54) ELECTRONIC EQUIPMENT WITH SEPARABLE COMMUNICATIONS ELEMENTS AND ELECTRONIC SYSTEM HAVING THE SAME

(75) Inventors: WEI WU, Shenzhen City (CN); XIN YANG, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/195,029

(22) Filed: Aug. 1, 2011

(30) Foreign Application Priority Data
Sep. 17, 2010 (CN) 201010284944.8

(51) Int. Cl. H04B 7/24; H05K 5/00

(52) U.S. Cl. 455/39; 361/679.01

(57) ABSTRACT

An exemplary piece of electronic equipment includes a first communications element and a second communications element. The first communications element includes a first housing, a first interface mounted on the first housing, and a first transceiver mounted in the first housing. The first transceiver is electrically connected to the first interface. The second communications element is electrically connected to the first communications element, and includes a second housing, a second interface mounted on the second housing, and a second transceiver mounted in the second housing. The second transceiver communicates with the first transceiver. The second transceiver is electrically connected to the second interface. The first communications element is electrically connected to the second communications element, and cooperates with the second communications element to form the electronic equipment with double the memory capacity.

### BACKGROUND

1. Technical Field

The present disclosure relates to electronic equipment and, particularly, to electronic equipment having separable communications elements and an electronic system having such electronic equipment.

2. Description of Related Art

Electronic equipment, such as a Universal Serial Bus (USB) flash disk, typically includes a housing and an interface mounted on the housing. The interface is used to electrically connect the electronic equipment to an external electronic device such as notebook computer, mobile phone, etc, thereby establishing communications between the electronic equipment and the external electronic device. However, one piece of electronic equipment usually includes only one interface, so that the electronic equipment can only be connected to one external electronic device. This limits the versatility of the electronic equipment.

Therefore, what is needed is electronic equipment with a mobile communications function to overcome the described limitations.

### BRIEF DESCRIPTION OF THE DRAWINGS

FIG. 1 is an isometric view of a piece of electronic equipment in accordance with a first exemplary embodiment, the electronic equipment comprising a first communications element and a second communications element.

FIG. 2 is an exploded view of the electronic equipment of FIG. 1.

FIG. 3 shows the electronic equipment of FIG. 1 being electrically connectable to any of a variety of external electronic devices.

FIG. 4 is similar to FIG. 3, but showing the first communications element and the second communications element of the electronic equipment disconnected from each other, with the first communications element being electrically connectable to any of the variety of external electronic devices.

FIG. 5 is an isometric view of a piece of electronic equipment in accordance with a second exemplary embodiment.

FIG. 6 is an isometric view of a piece of electronic equipment in accordance with a third exemplary embodiment.

### DETAILED DESCRIPTION

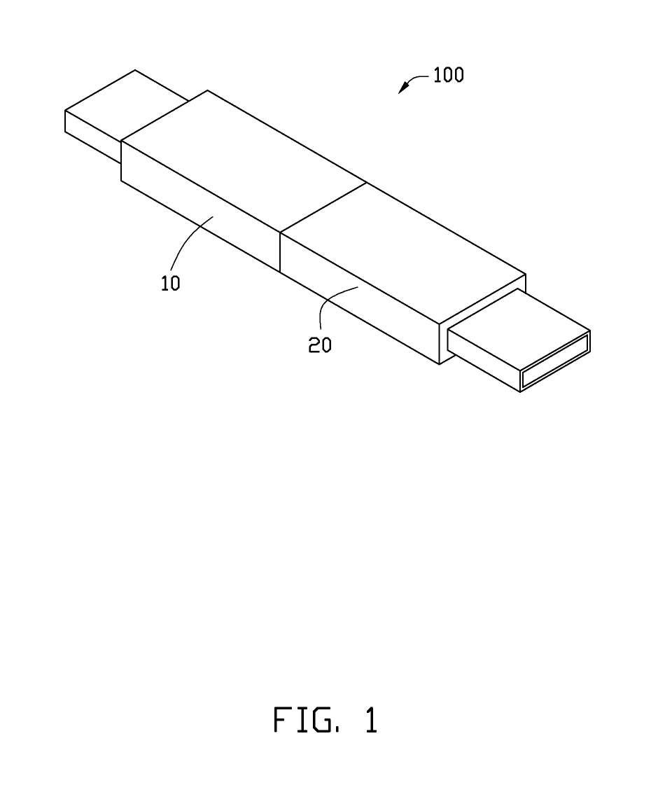

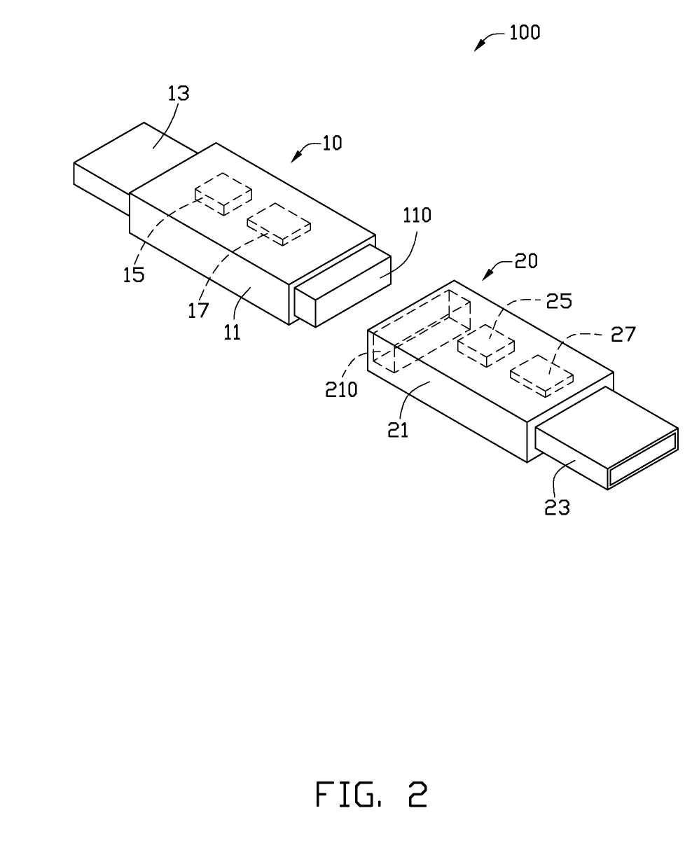

Referring to FIGS. 1-2, a piece of electronic equipment 100 in accordance with a first exemplary embodiment is shown. The electronic equipment 100 includes a first communications element 10, and a second communications element 20 electrically connected to the first communications element 10. In one embodiment, the first communications element 10 and the second communications element 20 are storage devices. In other embodiments, the first communications element 10 and the second communications element 20 may be MP3 (Moving Picture Experts Group, audio layer 3) players, mobile hard disks, etc.

The first communications element 10 includes a first housing 11, a first interface 13, a first transceiver 15, and a first power supply 17. The first interface 13 is mounted on one end of the first housing 11. The first transceiver 15 is mounted in the first housing 11. The first interface 13 is electrically connected to the first transceiver 15. The first power supply 17 is mounted within the first housing 11, and supplies power to the first communications element 10. A plug 110 is mounted on an opposite end of the first housing 11.

The second communications element 20 is similar to the first communications element 10, and includes a second housing 21, a second interface 23, a second transceiver 25, and a second power supply 27. The second interface 23 is mounted on one end of the second housing 21. The second transceiver 25 is mounted in the second housing 21, and communicates with the first transceiver 15. The second interface 23 is electrically connected to the second transceiver 25. The second power supply 27 is mounted within the second housing 21, and supplies power to the second communications element 20. A jack 210 is defined in an opposite end of the second housing 21. The jack 210 is configured for receiving the plug 110, thereby electrically connecting the first communications element 10 to the second communications element 20.

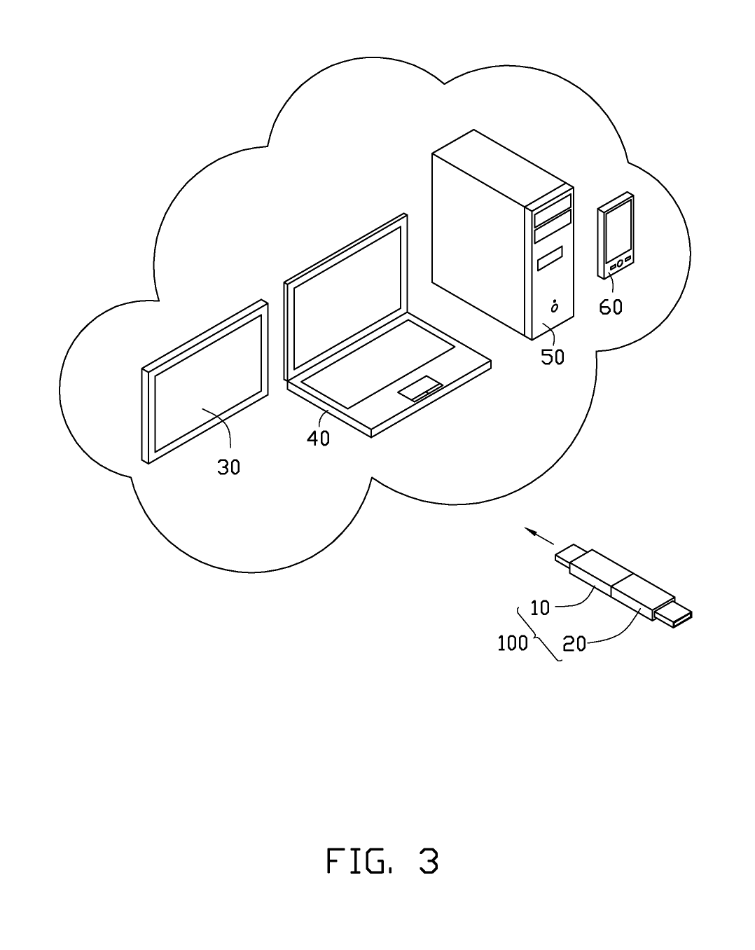

When the plug 110 of the first communications element 10 is inserted into the jack 210 of the second communications element 20, the first communications element 10 is electrically connected to the second communications element 20, and cooperates with the second communications element 20 to form the electronic equipment 100 with double the memory capacity. Then, the user can choose to insert the first interface 13 or the second interface 23 into an electronic device, thereby electrically connecting the electronic equipment 100 to the electronic device. As shown in FIG. 3, one of the first interface 13 and the second interface 23 is insertable into the electronic device, such as a tablet computer 30, a notebook computer 40, a server 50, a mobile phone 60, etc, thereby electrically connecting the electronic equipment 100 to the electronic device.

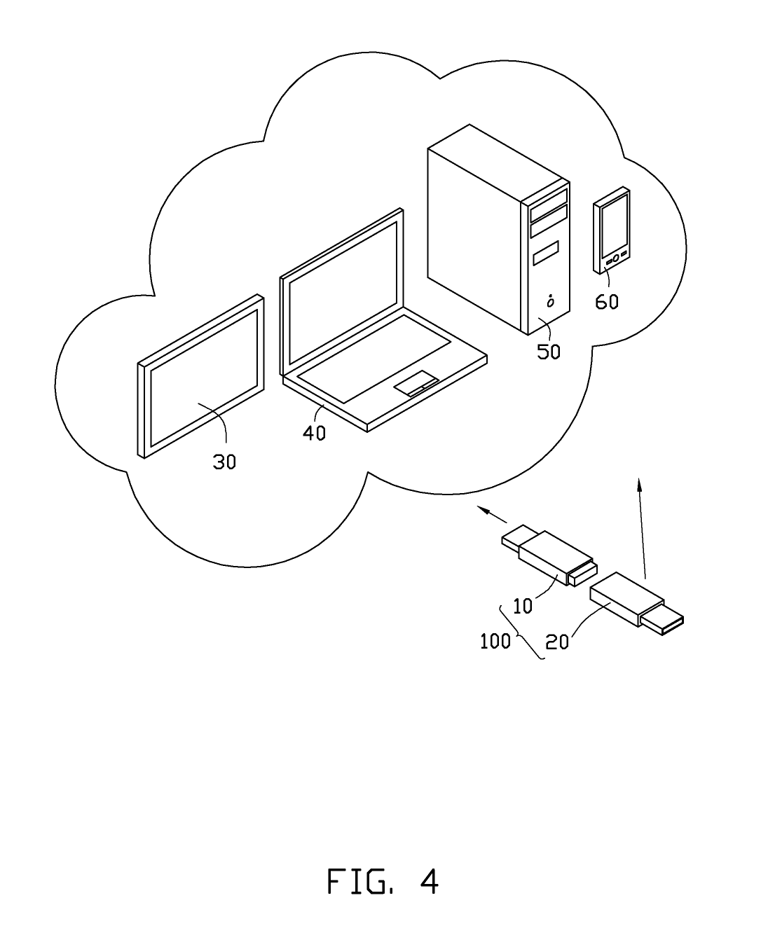

When the first communications element 10 and the second communications element 20 are disconnected from each other, and one of the first communications element 10 and the second communications element 20 remains electrically connected to the external electronic device, the first transceiver 15 can communicate with the second transceiver 25. Thereby, a communications link between the external electronic device and the entire electronic equipment 100 is established. As shown in FIG. 4, the first communications element 10 and the second communications element 20 are disconnected from each other, the first interface 13 of the first communications element 10 is electrically connected to the electronic device (such as the tablet computer 30, the notebook computer 40, the server 50, or the mobile phone 60), and the second interface 23 is not electrically connected to any external device. The first transceiver 15 may communicate with the second transceiver 25 to establish the communications link between the electronic device and the entire electronic equipment 100.

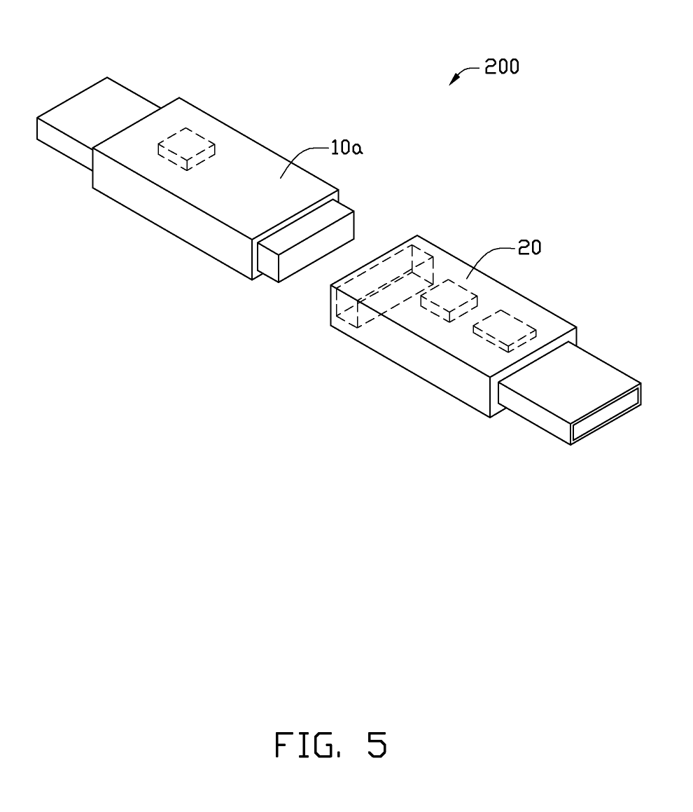

Referring to FIG. 5, a piece of electronic equipment 200 in accordance with a second exemplary embodiment is shown. Compared with the electronic equipment 100, the first communications element 10a of the electronic equipment 200 does not include the power supply 17. Instead, the first communications element 10a obtains power from an external source (such as an electronic device) which is electrically connected to the first communications element 10a.

For example, when the first communications element 10a is electrically connected to the second communications element 20, the second communications element 20 supplies power to the first communications element 10a. When the first communications element 10a and the second communications element 20a are disconnected from each other, the first communications element 10a can remain electrically connected to an external electronic device. With this arrangement, the external electronic device can supply power for the first communications element 10a. In addition, the first transceiver 15 communicates with the second transceiver 25 to establish a communications link between the external electronic device and the entire electronic equipment 200.

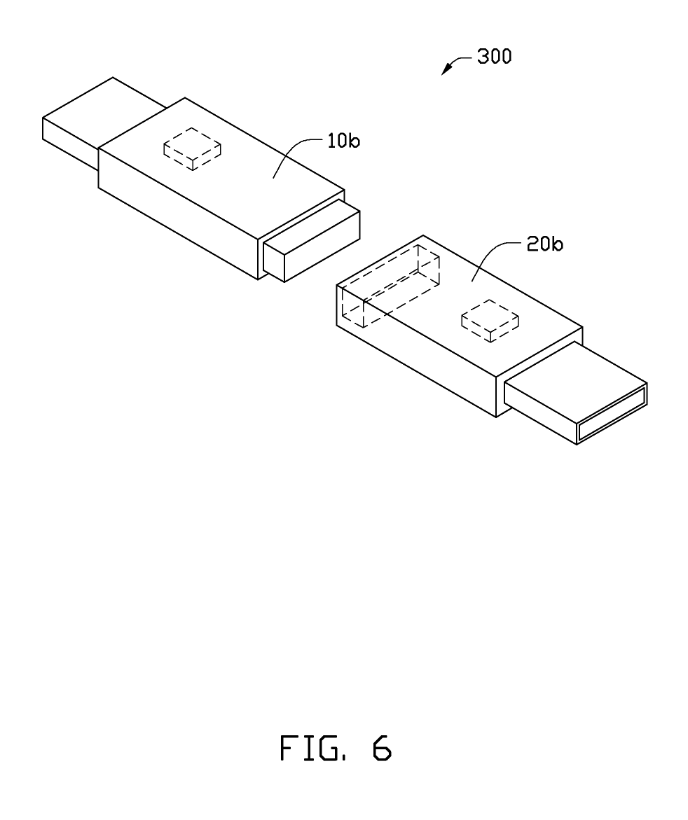

Referring to FIG. 6, a piece of electronic equipment 300 in accordance with a third exemplary embodiment is shown. Compared with the electronic equipment 100, the first communications element 10b and the second communications element 20b do not include the first power supply 17 and the second power supply 27. Instead, the electronic equipment 300 obtains power from two external electronic devices which are respectively electrically connected to the first communications element 10b and the second communications element 20b.

For example, when the first communications element 10b is electrically connected to the second communications element 20b, and one of the first communications element 10b and the second communications element 20b is electrically connected to an external electronic device, the external electronic device supplies power for both the first communications element 10b and the second communications element 20b. When the first communications element 10b and the second communications element 20b are disconnected from each other, the first communications element 10b can remain electrically connected to one of the external electronic devices, and the second communications element 20b can remain electrically connected to the other external electronic device. With this arrangement, the corresponding external electronic devices supply power for the first communications element 10b and the second communications element 20b, respectively. In addition, the first transceiver 15 communicates with the second transceiver 25 to establish a communications link between each of the two external electronic devices and the entire electronic equipment 300.

Although the present disclosure has been specifically described on the basis of exemplary embodiment thereof, the disclosure is not to be construed as being limited thereto. Various changes or modifications may be made to the embodiments without departing from the scope and spirit of the disclosure.

What is claimed is:

1. An electronic equipment comprising:
a first communications element comprising:
a first housing;
a first interface mounted on the first housing; and
a first transceiver mounted in the first housing, and electrically connected to the first interface; and
a second communications element mechanically and electrically connectable to and disconnectable from the first communications element, and comprising:
a second housing;
a second interface mounted on the second housing; and
a second transceiver mounted in the second housing, and electrically connected to the second interface, wherein the first transceiver and the second transceiver are configured to communicate with each other.

2. The electronic equipment as described in claim 1, wherein a plug is mounted on the first housing, a jack is defined in the second housing, the plug is insertable into the jack to electrically connect the first communications element to the second communications element.

3. The electronic equipment as described in claim 2, wherein the first interface is mounted on one end of the first housing, the plug is mounted on opposite end of the first hosing, and the second interface is mounted on one end of the second housing, the jack is defined in opposite end of the second housing.

4. The electronic equipment as described in claim 2, wherein when the first communications element is electrically connected to the second communications element, the electronic equipment is electrically connected to an external electronic device by the first interface or the second interface.

5. The electronic equipment as described in claim 1, wherein when the first communications element and the second communications element are disconnected from each other, and are respectively electrically connected to an electronic device, the first transceiver communicates with the second transceiver to establish the communications link between the two electronic devices and the electronic equipment.

6. The electronic equipment as described in claim 1, wherein one of the first communications element and the second communications element comprises a power supply, when the first communications element and the second communications element are disconnected from each other, the first communications element or the second communications element without the power supply remains electrically connected to an electronic device, the first transceiver communicates with the second transceiver to establish the communications link between the electronic device and the electronic equipment.

7. The electronic equipment as described in claim 6, wherein when the first communications element is electrically connected to the second communications element, the first communications element or the second communications element with the supply power supplies power for the first communications element or the second communications element without the supply power.

8. The electronic equipment as described in claim 1, wherein the first communications element further comprises a first power supply for supplying power for the first communications element, the second communications element further comprises a second power supply for supplying power for the second communications element, when the first communications element and the second communications element are disconnected from each other, the first communications element or the second communications remains electrically connected to an electronic device, the first transceiver communicates with the second transceiver to establish the communications link between the electronic device and the electronic equipment.

9. An electronic system comprising:
two electronic devices; and
an electronic equipment comprising:
a first communications element comprising:
a first housing;
a first interface mounted on the first housing; and
a first transceiver mounted in the first housing, and electrically connected to the first interface; and
a second communications element mechanically and electrically connectable to and disconnectable from the first communications element, comprising:
a second housing;
a second interface mounted on the second housing; and
a second transceiver mounted in the second housing, and electrically connected to the second interface;
wherein the first interface is mechanically and electrically connectable to at least one of the two electronic devices, the second interface is mechanically and electrically connectable to at least the other one of the two electronic devices, and the first transceiver and the second transceiver are configured to communicate with each other;
whereby when the first interface is connected to one of the two electronic devices, the second interface is connected to the other one of the two electronic devices, and the first communications element and the second communications element are disconnected from each other, then the first transceiver and the second transceiver are operable to establish communication between each of the two electronic devices and the entire electronic equipment.

10. An electronic system comprising:
an electronic device; and
an electronic equipment comprising:
a first communications element comprising:
a first housing;
a first interface mounted on the first housing; and
a first transceiver mounted in the first housing, and electrically connected to the first interface; and
a second communications element mechanically and electrically connectable to and disconnectable from the first communications element, the second communications element comprising:
a second housing;
a second interface mounted on the second housing; and
a second transceiver mounted in the second housing, and electrically connected to the second interface;
wherein the first transceiver and the second transceiver are configured to communicate with each other such that when one of the first interface and the second interface is mechanically and electrically connected to the electronic device and the first communications element and the second communications element are disconnected from each other, the first transceiver and the second transceiver are operable to establish communication between the electronic device and the entire electronic equipment.
